(19) United States
(12) Patent Application Publication
(10) Pub. No.: US 2026/0013203 A1
(43) Pub. Date: Jan. 8, 2026

(54) GATE ALL AROUND DEVICE WITH A WORK FUNCTION MISMATCH BETWEEN INNER AND OUTER GATES

(71) Applicants: IMEC VZW, Leuven (BE); HUAWEI TECHNOLOGIES CO., LTD., Shenzhen, Guangdong (CN)

(72) Inventors: Philippe Matagne, Grivegnée (BE); Geert Hellings, Halle (BE); Krishna Kumar Bhuwalka, Heverlee (BE); Gautam Gaddemane, Leuven (BE)

(21) Appl. No.: 19/111,983

(22) PCT Filed: Sep. 16, 2022
(86) PCT No.: PCT/EP2022/075769

§ 371 Date: Mar. 14, 2025

(51) Int. Cl. H10D 64/66; H10D 30/00; H10D 30/01; H10D 62/10; H10D 62/80; H10D 62/832; H10D 62/85; H10D 84/83; H10D 84/85

(52) U.S. Cl. CPC H10D 64/669; H10D 30/0191; H10D 30/502; H10D 84/83135; H10D 84/851; H10D 62/121; H10D 62/832; H10D 62/85; H10D 62/881

(57) ABSTRACT

The present disclosure relates to a gate all around (GAA) device made based on a GAA transistor structure that comprises a stack of multiple semiconductor channel layers and one or more first gate layers alternatingly arranged along a first direction. Each channel layer is encapsulated by a gate dielectric layer, and each first gate layer is arranged between two channel layers following another. The GAA transistor structure further comprises two second gate layers sandwiching the stack in a second direction and connected to the first gate layers. Each first gate layer is made of a first work function metal structure and each second gate layer is made of a second work function metal structure that is different from the first work function metal structure. Each first gate layer has a first thickness and each second gate layer has a second thickness larger than the first thickness.

### FIELD OF THE DISCLOSURE

The present disclosure relates to a gate all around (GAA) device, and to a GAA transistor structure, based on which the GAA device can be fabricated. The proposed GAA transistor structure provides the GAA device with a work function mismatch between inner gates formed between the channel layers and outer gates formed around the channel layers and the inner gates.

### BACKGROUND

A GAA device comprises a plurality of stacked semiconductor channel layers and a GAA metal structure, which surrounds the stack of semiconductor channel layers and each individual channel layer. Each channel layer is surrounded by a gate dielectric layer to isolate it from the GAA metal structure. As an example, a GAA nanosheet device comprise a plurality of stacked semiconductor nanosheets as the channel layers. Another example is a GAA forksheet device that integrates NMOS and PMOS nanosheet structures each aside of a dielectric wall separating the NMOS from PMOS nanosheet structures. All these GAA devices are candidates for future CMOS logic, in particular, are envisioned as a replacement for FinFET devices.

Vertical scaling of GAA devices by increasing the number of the stacked channel layers is desired, for instance, to implement complementary field effect transistor (CFET) structures. Unfortunately, the vertical scaling degrades the device performance, particularly the device speed, due to an increase of the effective capacitance of the GAA device. One way to facilitate vertical scaling is to scale down the pitch or distance between the stacked semiconductor channel layers, since this reduces the effective capacitances and thus enhances the performance of the GAA device.

However, if the pitch is scaled down, the space between the channel layers of the stack becomes more confined. This is especially true for input/output (I/O) devices which require a thicker gate oxide compared to logic devices.

As a further consequence, the design of the GAA metal structure of the GAA device becomes more difficult, and may lead to performance loss. For instance, a work function design of the GAA metal structure is difficult and technologically complex. In particular, if the design and fabrication process should allow for fabricating different variants of the GAA device having different threshold voltages (multi-Vt-options). These difficulties are exacerbated in case of high-example embodiment ratio GAA devices.

### SUMMARY

The present disclosure provides a solution for scaling down the pitch between the stacked channels layers of a GAA device, in order to improve the device performance. The present disclosure further provides a solution for designing a GAA metal structure for such a scaled-down GAA device, wherein the GAA metal structure should be easy to manufacture, should provide good gate control over the channel layers, and should lead to a good device performance. The present disclosure provides a solution for multi-Vt-options.

embodiment The present disclosure and the solutions proposed therein are based on the realization that it is not crucial for the device performance of a GAA device with a small channel layer pitch below 15 nm to have exactly the same threshold voltage (Vt) around and in between the channels, i.e., the exact same threshold voltage for the outer gates and the inner gates. Some mismatch in threshold voltage between the outer gates and the inner gates has a negligible effect on the device performance of the GAA device, as demonstrated further below.

A first example embodiment of this disclosure provides a GAA transistor structure comprising: a stack of two or more semiconductor channel layers and one or more first gate layers alternatingly arranged along a first direction; wherein each semiconductor channel layer is encapsulated by a gate dielectric layer, and wherein each first gate layer is arranged between two of the semiconductor channel layers following each other in the first direction; and two second gate layers sandwiching the stack in a second direction perpendicular to the first direction and connected to the one or more first gate layers; wherein each first gate layer is made of a first work function metal structure and each second gate layer is made of a second work function metal structure that has a different work function than the first work function metal structure; and wherein each first gate layer has a first thickness and each second gate layer has a second thickness that is larger than the first thickness.

The GAA transistor structure of the first example embodiment can be used to build a GAA device. The first gate layers may form the inner gates in the GAA device, and the second gate layers may form the outer gates (in particular, side gates) in the GAA device.

The first work function metal structure may be made of a single metal layer that has a first work function, or may be made of multiple metal layers having (together as the structure) the first work function. Each first work function metal structure is configured to act as a first gate. The second work function metal structure may be made of a single metal layer that has a second work function, or may be made of multiple metal layers having (together as the structure) the second work function. Each second work function metal structure is configured to act as a second gate.

Accordingly, the first work function is different from the second work function, i.e. there is a work function mismatch in the GAA transistor structure between the first gate layers and the second gate layers, and thus also in a GAA device, which is made based on the GAA transistor structure, between the inner gates and the outer gates. As a consequence, there may also be a mismatch in the threshold voltages of the transistor structures formed the inner gates and the transistor structures formed by the outer gates in the GAA device. However, this mismatch does not impact significantly the performance of the GAA device. For the GAA device made from the GAA transistor structure of this disclosure, a decrease of the on-current is at most 10% or even lower. The work function mismatch makes the design and fabrication of the GAA metal structure of the GAA device, which comprises the first gate layers and second gate layers, easier and less complex from a technological point of view.

Further, the first gate layers are thinner than the second gate layers, wherein the first thickness is measured along the first direction, and the second thickness is measured along the second direction. This enables scaling down the distance(s) or the pitch between the semiconductor channel layers of the stack. This down-scaling leads to a decrease of the effective capacitance of the GAA device, which improves the device performance, particularly the device speed. The increase in performance easily offsets any performance loss caused by the above-mentioned mismatch-induced decrease of the on-current. The down-scaling of the pitch allows further vertical scaling of the GAA transistor structure, i.e., increasing the number of channel layers in the stack. It may also lead to a simpler processing of the GAA transistor structure, due to a reduced stack height, if the number of channel layers is kept the same.

In an embodiment of the GAA transistor structure, a ratio of the second thickness to the first thickness is in equal to or larger than 4:1.

In an embodiment of the GAA transistor structure, the first thickness is in a range of 1-2 nm, and the second thickness is in a range of 5-7 nm.

According to the above embodiments, very thin first gate layers (i.e., very thin inner gates in the GAA device made from the GAA transistor structure) are possible, and facilitate scaling-down the channel layer pitch.

In an embodiment of the GAA transistor structure, a difference between a first work function of the first work function metal structure and a second work function of the second work function metal structure is in a range of −250 meV to +250 meV.

At least in this range of ±250 meV work function mismatch between the first gate layers and the second gate layers, a performance of a GAA transistor structure, respectively of an exemplary GAA device made based on the GAA transistor structure, for example, with four channel layers and a channel layer pitch of 11 nm is not significantly impacted. Other exemplary GAA devices may even allow for a larger work function mismatch. In particular, the first work function of the first work function metal structure may be higher than the second work function of the second work function metal structure, but the first work function may also be lower than the second work function.

In an embodiment of the GAA transistor structure, the GAA transistor structure is an NMOS transistor structure, the first work function is in a range of 4.4-4.6 eV, and the second work function is in a range of the first work function ±250 meV.

In an embodiment of the GAA transistor structure, the GAA transistor structure is a PMOS transistor structure, the first work function is in a range of 4.6-4.8 eV, and the second work function is in a range of the first work function ±250 meV.

The GAA transistor structure may also be a CFET transistor structure, which implements both NMOS and PMOS transistor structures.

In an embodiment of the GAA transistor structure, the semiconductor channel layers are arranged with a pitch along the first direction, and wherein the pitch is equal to or below 13 nm.

The pitch is relevant for a case in which the semiconductor channel layers are arranged with a regular distance along the first direction, i.e., any two adjacent channel layers are arranged with the same distance to each other. This distance may be measured from the center of one channel layer to the center of the adjacent channel layer along the first direction. The pitch may be smaller, for instance, the pitch may be 11 nm or lower, or the pitch may be 10 nm or lower, or the pitch may even be 8 nm or lower.

Notably, the distance between adjacent channel layers does not have to be constant in the stack of the GAA transistor structure of the first example embodiment. For instance, a first distance between a first pair of channel layers in the stack may be different than a second distance between a second pair of channel layers in the stack. Either one of the first distance and the second distance, or both of the first distance and the second distance, may be equal to 13 nm or less. Thus, also a GAA transistor structure with a variable separation between the channel layers in the stack is possible.

In an embodiment of the GAA transistor structure, the second work function metal structure comprises a set of metal layers, and the first work function metal structure comprises a subset of metal layers included in the set of metal layers.

The set of metal layers of the second work function metal structure may comprise different kinds of metal layers. The set of metal layers of the second work function metal structure (provided together) may have the second work function. The subset of metal layers of the first work function metal structure may comprise one or more different kinds of metal layers. A least one of these metal layers may be included in both the set of metal layers and the subset of metal layers. The set of metal layers of the first work function metal structure (provided together) may have the first work function. The two work function metal structures are work function mismatched.

In an embodiment of the GAA transistor structure, the second work function metal structure consist of three metal layers respectively made of titanium nitride, tantalum nitride, and titanium aluminide.

These metal layers are an example that leads to good device performance results of a GAA device made based on the GAA transistor structures. The titanium nitride layer, the tantalum nitride layer, and the titanium aluminide layer may form the set of metal layers mentioned above. The tantalum nitride layer may be arranged on the titanium nitride layer, and the titanium aluminide layer may be arranged on the tantalum nitride layer. In this case, the titanium nitride layer and the titanium aluminide layer sandwich the tantalum nitride layer.

In an embodiment of the GAA transistor structure, the first work function metal structure consist of a single metal layer made of titanium nitride, or consist of two metal layers respectively made of titanium nitride and tantalum nitride.

That is, at least the titanium nitride may be included in the second work function metal structure and the first work function metal structure. The titanium nitride layer, or the titanium nitride layer and the tantalum nitride layer, may form the subset of metal layers mentioned above.

In an embodiment, the GAA transistor structure further comprises two additional second gate layers sandwiching the stack in the first direction and connected to the one or more first gate layers and to the two second gate layers sandwiching the stack in the second direction.

These additional second gate layers may also form outer gates (especially top gates and bottom gates, compared to the side gates formed by the second metal layers) in a GAA device made based on the GAA transistor structure. The additional second gate layers and the second gate layers may be identical. The additional second gate layers are, for instance, made of the same second work function metal structure than the second gate layers, and have the same second thickness as the second gate layers (wherein for the additional second gate layers the second thickness is measured along the first direction).

In an embodiment, the GAA transistor structure further comprises an encapsulation, for example made of tungsten, around the stack and the second gate layers.

This encapsulation may protect the GAA metal structure, which comprises or consist of the second gate layers, the first gate layers, and optionally the additional second gate layers. The encapsulation may also protect the stack of channel layers. Furthermore, the encapsulation may be used to contact the GAA metal structure. Notably, the encapsulation may be designed such that it does not influence the work function(s) and specifically the work function mismatch between the second gate layers and the first gate layers.

In an embodiment of the GAA transistor structure, each semiconductor channel layer is formed by a nanosheet and/or is made of one of silicon, silicon germanium, a III-V semiconductor material, and a 2D material.

For instance, silicon nanosheets may be used as the channel layers. The two or more semiconductor channel layers may all be of the p-type, or may all be of the n-type, or may include both n-type and p-type channel layers. The channel layers may each have a channel width (measured along the second direction) in a range of 10-60 nm. At least in this range of channel widths, the device performance of a GAA device made based on the GAA transistor structure is stable.

In an embodiment of the GAA transistor structure, first field effect transistor (FET) structures are formed by the first gate layers, the gate dielectric layers encapsulating the semiconductor channel layers, and the semiconductor channel layers; and second FET structures are formed by the second gate layers, the gate dielectric layers encapsulating the semiconductor channel layers, and the semiconductor channel layers; wherein each first FET structure has a first threshold voltage and each second FET structure has a second threshold voltage different than the first threshold voltage.

This threshold voltage mismatch, which is caused by the work function mismatch described in this disclosure, does not impact significantly the device performance of a GAA device made based on the GAA transistor structure, and allows the scaling of the pitch between the channel layers, without having to design and fabricate a complex GAA metal structure.

A second example embodiment of this disclosure provides a GAA device comprising the GAA transistor structure according to the first example embodiment or any embodiment form thereof, wherein the GAA device is a logic device or an input/output device.

The GAA device of the second example embodiment is accordingly made based on the GAA transistor structure of the first example embodiment. In addition to the GAA transistor structure, the GAA device may comprise a source contact and a drain contact to contact the channel layers. For instance, source and drain contact may be arranged on opposite sides of the stack along a third direction perpendicular to the first direction and the second direction, and may contact the channel layers in the third direction. The GAA device may further comprise gate contacts to contact the first gate layers and the second gate layers, for instance, to commonly contact the GAA metal structures, which comprises the first gate layers and the second gate layers. The GAA device may notably comprise multiple GAA transistor structures according to the first example embodiment, wherein in such a GAA device different types of transistor structures (e.g., NMOS and PMOS) may be combined.

For the GAA device being a logic device, the reduction of the channel layer pitch, which is achieved by the GAA transistor structure of the first example embodiment, results in a net increase in speed, in spite of a small possible loss in drive current (on-current). Further, the GAA device being an I/O device means that the GAA transistor structure of the first example embodiment enables the I/O devices to remain process compatible with their logic device counterparts, even though they may require thicker gate dielectric layers.

A third example embodiment of this disclosure provides a method for fabricating a GAA transistor structure, the method comprising: forming a stack of two or more semiconductor channel layers and one or more first gate layers alternatingly arranged along a first direction; wherein each semiconductor channel layer is encapsulated by a gate dielectric layer, and wherein each first gate layer is arranged between two of the semiconductor channel layers following each other in the first direction; and forming two second gate layers sandwiching the stack in a second direction perpendicular to the first direction and connected to the one or more first gate layers; wherein each first gate layer is made of a first work function metal structure and each second gate layer is made of a second work function metal structure that has a different work function than the first work function metal structure; and wherein each first gate layer has a first thickness and each second gate layer has a second thickness that is larger than the first thickness.

According to the above example embodiments, the present disclosure provides a GAA transistor structure and a GAA device, respectively, considering thin first gate layers to make inner gates, and a work function mismatch between the second gate layers, which are used to make outer gates, and the first gate layers.

Simulations (TCAD) show that by varying the first work function of the first gate layers by ±250 meV compared to the second work function of the second gate layers achieves very good device performance (e.g., device speed) for both logic devices and I/O devices. The simulations were performed for GAA devices with 11 nm channel layer pitch and four channel layers in the stack. The simulations particularly show that the loss in on-current is not more than 9% and 3% for logic devices and I/O devices, respectively. The simulations demonstrate that the channel layer pitch can be scaled down, for example, to 11 nm, which results in a significant reduction of the effective capacitance and increases the device speed significantly.

### BRIEF DESCRIPTION OF THE DRAWINGS

The above described example embodiments are explained in the following description of embodiments with respect to the enclosed drawings:

FIG. 1 shows a GAA transistor structure according to the present disclosure.

FIG. 2 shows an exemplary GAA transistor structure according to the present disclosure.

FIG. 3 shows an example for a first work function metal structure of a first gate layer, and an example for a second work function metal structure of a second gate layer, in a GAA transistor structure according to the present disclosure.

FIG. 4 shows a flow-diagram of one method fabricating a GAA transistor structure according to the present disclosure.

FIG. 5 shows results of an exemplary GAA device according to this disclosure, which is made based on a GAA transistor structure according to the present disclosure.

### DETAILED DESCRIPTION

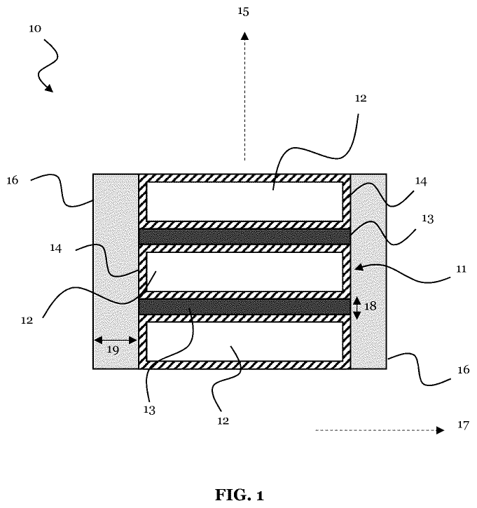

FIG. 1 shows a GAA transistor structure 10 according to an embodiment of this disclosure. The GAA transistor 10 may be included in a GAA device according to another embodiment of this disclosure. The GAA device may be a nanosheet device or a forksheet device.

The GAA transistor structure 10 comprises a stack 11 of two or more semiconductor channel layers 12 and one or more first gate layers 13, wherein the channel layers 12 and the first gate layers 13 are alternatingly arranged along a first direction 15 (vertical in FIG. 1). Each first gate layer 13 is arranged between two of the semiconductor channel layers 12, which follow each other in the stack 11 along the first direction 15. That is, the stack 11 starts with a first channel layer 12, and then alternatingly a first gate layer 11 and then another channel layer 12 are provided to form the stack on the first channel layer 12. Each of the channel layers 12 is encapsulated by a gate dielectric layer 14, so as to isolate and separate the channel layer 12 from the first gate layer(s) 13 arranged adjacent to it. The gate dielectric layer 14 may be a single layer or a dielectric layer stack. A first FET structure may be formed by each first gate layer 13, the semiconductor channel layer 12 adjacent to this first gate layer 13, and the gate dielectric layer 14 separating this first gate layer 13 from the adjacent channel layer 12.

The GAA transistor structure 10 further comprises two second gate layers 16, wherein the two second gate layers 16 sandwich the stack 11 in a second direction 17 (horizontal in FIG. 1), which is perpendicular to the first direction 15. That is, one second layer 16 is arranged on either side, of the two opposite sides in the second direction 17, of the stack 11. Notably, if the GAA transistor structure 10 is for a GAA forksheet device, the stack 11 may be separated by a dielectric wall into a first part of the stack 11 and a second part of the stack, which are arranged besides each other along the second direction 17. The first part of the stack 11 may comprise NMOS channel layers, and the second part of the stack 11 may comprise PMOS channel layers. In this case, one of the two second gate layers 16 and the dielectric wall sandwich the first part of the stack 11 in the second direction 17, while the other one of the two second gate layers 16 and the dielectric wall sandwich the second part of the stack 11 in the second direction 17.

The second gate layers 16 are further connected to the one or more first gate layers 13. The second gate layers 16 and the first gate layers 13 may be both part of a GAA metal structure of the GAA transistor structure 10, or respectively of the GAA device made based on the GAA transistor structure 10. A second FET structure may be formed by each second gate layer 16, any semiconductor channel layer 12 (note that each channel layer is adjacent to both second gate layer 16), and the gate dielectric layer 14 encapsulating this channel layer 12. Each gate dielectric layer 14 also isolates and separates the channel layer 12, which it encapsulates, from the second gate layers 16.

Further, each first gate layer 13 of the GAA transistor structure 10 is made of a first work function metal structure, and each second gate layer 16 is made of a second work function metal structure. A work function metal structure may include one or more work function metals or metal layers. The first work function metal structure has a different work function than the second work function metal structure. In particular, a first work function of the first work function metal structure is different from a second work function of the second work function metal structure. For example, the difference between the first work function of the first work function metal structure and the second work function of the second work function metal structure is in a range of −250 meV to +250 meV. That is, either the first work function is larger than the second work function, or the second work function is larger than the first work function.

Further, each first gate layer 13 of the GAA transistor structure 10 has a first thickness 18 along the first direction 15, and each second gate layer 16 has a second thickness 19 along the second direction 17, wherein the second thickness 19 is larger than the first thickness 18. For example, the first thickness 18 may be 1 nm or 2 nm or anywhere between 1 and 2 nm, and the second thickness 19 may be 5 nm, or 6 nm, or 7 nm, or anywhere between 5 nm and 7 nm. Optionally, a ratio of the second thickness 19 to the first thickness 18 may be equal to or larger than 4:1, for example, equal to or larger than 5:1, or even equal to or larger than 6:1.

Accordingly, there is both a work function mismatch and a thickness mismatch between the first gate layers 13, which will form the inner gates in a GAA device made based on the GAA transistor structure 10, and the second gate layers 16, which will form the outer gates (particularly the side gates) in the GAA device.

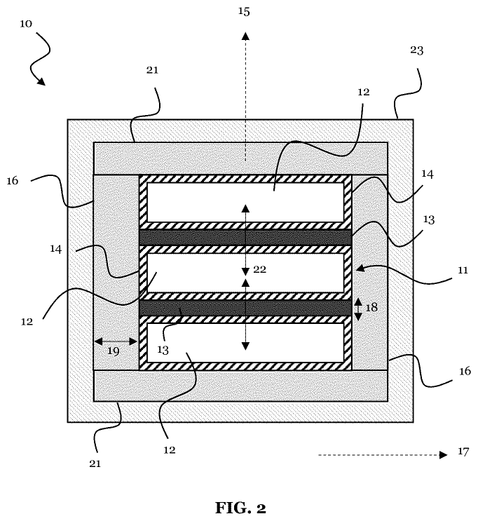

FIG. 2 shows a GAA transistor structure 10 according to an exemplary embodiment of this disclosure. The GAA transistor structure 10 of FIG. 2 may have further optional features compared to the GAA transistor structure 10 of FIG. 1. Each of these optional features may be added individually to the GAA transistor structure 10 of FIG. 1, or in any combination with others of the optional features.

As shown in FIG. 2, the two or more semiconductor channel layers 12 of the GAA transistor structure 10 may be arranged with a pitch 22 along the first direction 15. The pitch 22 may be equal to or below 13 nm, as described above. The pitch 22 may vary along the first direction 15, e.g., not each two adjacent semiconductor channel layers 12 along the first direction 15 must have the same distance between each other. However, in one possible embodiment the pitch 22 is constant in the stack 11, i.e., any two adjacent semiconductor channel layers 12 along the first direction 15 have the same distance (corresponding to the pitch 22) to each other. This distance may be measured from center to center of the two adjacent channel layers 12.

As further shown in FIG. 2, the GAA transistor structure 10 may further comprise two additional second gate layers 21 sandwiching the stack 11 in the first direction 15. That is, one of these additional second gate layers 21 may be arranged below the stack 11, and the other one above the stack 11, with respect to the first direction 15. It is also possible to have only one additional second gate layer 21 arranged above or below the stack 11. The second gate layers 12 and the additional second gate layers 21 may be designed similarly, in particular, may have the same second thickness 19 and may be made of the same second work function metal structure. The additional second gate layers 21 are connected to the one or more first gate layers 13 and to the two second gate layers 16, which are sandwiching the stack 11 in the second direction 17. The first gate layers 13, the second gate layers 16, and the additional second gate layers 21 may form the GAA metal structure of a GAA device made based on the GAA transistor structure 10. This GAA metal structure surrounds the channel layers 12, which are encapsulated by the gate dielectric layers 14, in the first direction 15 and the second direction 17. The channel layers 12 are surrounded both individually and as a stack 11 in the first direction 15 and second direction 17.

As further shown in FIG. 2, the GAA transistor structure 10 may further comprise an encapsulation 23, which may protect the stack 11 and the first and second gate layers 13, 16, 21, respectively. For example, the encapsulation 23 may be made of tungsten or another metal material. The encapsulation 23 may be arranged at least partly around the stack 11 and the (additional) second gate layers 16, 21. The encapsulation 23 may be further used for contacting the gate layers 13, 16, 21. For instance, one or more gate contacts can be used to contact the GAA metal structure formed by these gate layers 13, 16, 21. The stack 11, and optionally the two additional gate layers 21, may in total be arranged on a substrate. Also the encapsulation 23 may be arranged on the substrate and may surround the stack 11, and optionally the two additional gate layers 21, at the sides and the top.

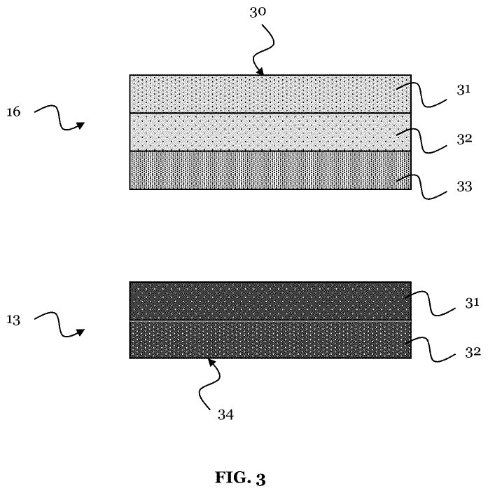

FIG. 3 shows examples of a first gate layer 13 and a second gate layer 16, respectively, as they may be implemented in the GAA transistor structure 10 of FIG. 1 or FIG. 2. In particular, FIG. 3 shows an example of the first work function metal structure 34, of which each first gate layer 13 is made, and an example of the second work function metal structure 30, of which each second gate layer 16 is made.

The second work function metal structure 30 shown in the upper part of FIG. 3 comprises multiple metal layers, for example, a set of metal layers. Here it exemplarily comprises three metal layers 31, 32 and 33. The second work function metal structure 30 may particularly consist of these metal layers 31, 32, 33. The first work function metal structure shown in the lower part of FIG. 3 comprises multiple metal layers as well, for example, a subset of metal layers. The subset of metal layers comprises metal layers that are included in the set of metal layers. Here, it exemplarily comprises metal layers 31 and 32 from the set of metal layers. The first work function metal structure 34 may consist of the subset of metal layers. For example, the first work function metal structure 34 may consist of only one layer 31, or may consist of two layers 31, 32 of the set of metal layers, of which the second work function metal structure 30 consists (notably, this is exemplarily indicated by same shadings in FIG. 3).

In a first example, the second work function metal structure 30 may consist of three metal layers that are, respectively, a titanium nitride layer 31, a tantalum nitride layer 32, and a titanium aluminide layer 33 (e.g., in this order). In a second example, the second work function metal structure 30 may consist of three metal layers that are, respectively, a first titanium nitride layer 31, a titanium aluminide layer 33, and a second titanium nitride layer 31 (e.g., in this order). In a third example, the second work function metal structure 30 may consist of five metal layers that are, respectively, a first titanium nitride layer 31, a tantalum nitride layer 32, a second titanium nitride layer 31, a titanium aluminide layer 33, and a third titanium nitride layer 31 (e.g., in this order). For instance, the first or second example may be used for an NMOS stack 11, and the third example may be used for a PMOS stack 11. The titanium aluminide may also comprise some carbon. The first work function metal structure 34 may consist of a subset of the metal layers of the second work function metal structure 30 according to the first, second, or third example. In examples, the first work function metal structure 34 may consist either of a single metal layer that is a titanium nitride layer 31, or may consist of two metal layers that are, respectively, a titanium nitride layer 31 and a tantalum nitride layer 32. Also a partial layer is possible for one layer of the subset of metal layers (compared to the same layer in the set of metal layers). For instance, the second work function metal structure 30 could consist of the titanium nitride layer 31, the tantalum nitride layer 32, and the titanium aluminide layer 33, while the first work function metal structure 34 consist of the titanium nitride layer 31 and a partial tantalum nitride layer 32, or of the titanium nitride layer, the tantalum nitride layer 32, and a partial titanium aluminide layer 33. Partial means reduced layer thickness. Other metal layers, which may be used in the set of metal layers and/or in the subset of metal layers, include a molybdenum nitride layer and a scandium oxide layer. The metal layers in the set of metal layers and/or in the subset of metal layers may also be made of any one of Ti, Ag, Al, TiAlN, TaC, TaCN, TaSiN, Mn, Zr, TiN, TaN, TiAl, Ru, Mo, Al, WN, Cu, W, Ir, Co, Ni, or any combination of these metals, or any other suitable metal material.

The first metal layer metal structure 34 has a first work function, and the second metal layer metal structure 30 has a second work function, wherein the first work function may depend on the individual work functions of the metal layers 31, 32 in the subset of metal layers used for the first work function metal structure 34 and their thicknesses. The second work function may depend on the work functions of the individual work functions of the metal layers 31, 32, 33 in the set of metal layers used for the second work function metal structure 30 and their thicknesses. Same metal layers in the set of metal layers and in the subset of metal layers may have the same respective thicknesses and work functions.

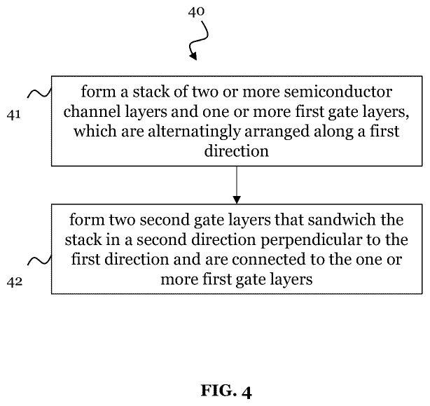

FIG. 4 shows a flow-diagram of steps of a method 40 for fabricating a GAA transistor structure 10, for instance, as shown in FIG. 1 and FIG. 2.

The method 40 generally comprises a step 41 of forming a stack 11 of two or more semiconductor channel layers 12 and one or more first gate layers 13, which are alternatingly arranged along a first direction 15. Each semiconductor channel layer 12 is encapsulated by a gate dielectric layer 14, i.e., the method 40 may comprise a step of encapsulating each channel layer 12 by a dielectric material. This may be a high-k material. The dielectric material of the gate dielectric layers 14 may also be silicon oxide and/or hafnium oxide. The material of the channel layers 12 may be silicon or a silicon-based material. Each first gate layer 13 is arranged between two of the two or more semiconductor channel layers 12 that are following each other in the first direction 15.

The method 40 further comprises a step 42 of forming 42 two second gate layers 16 sandwiching the stack 11 in a second direction 17 perpendicular to the first direction 15, wherein the two second gate layers 16 are connected to the one or more first gate layers 13.

Each first gate layer 13 is made of a first work function metal structure 34, and each second gate layer 16 is made of a second work function metal structure 30 that is different from the first work function metal structure 34. Each first gate layer 13 is made to have a first work function, and each second gate layer 16 is made to have a second work function. Further, each first gate layer 13 is made to have a first thickness 18, and each second gate layer 16 is made to have a second thickness 19 that is larger than the first thickness 18. The method 40 may also comprise a step of making the additional second gate layers 21 shown in FIG. 2, wherein these additional second gate layers 21 may be made to have the second work function and the second thickness 19 just like the second layers 16.

In an example for implementing the method 40 shown in FIG. 4, at first the channel layers 12 may be fabricated and respectively encapsulated with the gate dielectric layers 14. For instance, the channel layers 12 could be fabricated in a dummy stack, in which they are alternatingly arranged with dummy gate layers along the first direction 15. These dummy gate layers could then be selectively removed to leave only the channel layers 12 and gaps between the channel layers 12. Then, the encapsulation with the gate dielectric layers 14 could be done, however, the encapsulation with the gate dielectric layers 14 could also be done before the removal of the dummy gate layers. There may also be other ways to form the channel layers 12 with gaps in between.

Afterwards, a first metal material may be deposited, for instance, titanium nitride may be deposited. This first metal material may deposit into the gaps formed between the encapsulated channel layers 12. The first metal material may be simultaneously deposited also on the sides of the channel layers 12 in the second direction 17, and optionally on top of the upper-most channel layer 12 and/or below the bottom-most channel layer 12 in the first direction 15. The depositing of the first metal material could be suppressed at least below the bottom-most channel layer, e.g., by using a bottom dielectric isolation. The deposition of the first metal material may continue, until the gaps between the channel layers 12 are completely filled. These gaps could each have a size along the first direction 15 that corresponds to the first thickness 18 shown in FIG. 1. In this way, the first gate layers 13 may be formed by the deposition of the first metal material into the gaps, wherein the first metal material may include a single metal, for example titanium nitride, so that a titanium nitride layer 31 may form each first work function metal structure 34.

At the same time, during deposition of the first metal material into the gaps, the first metal material has also deposited with the same first thickness 18 (but along the second direction 17) on the sides of the channel layers 12. Now, a further deposition step may follow, wherein a second metal material may be deposited, for instance, tantalum nitride may be deposited. Since the gaps have already been filled completely by the first metal material, the second metal material will only deposit on the first metal material that is arranged on the sides of the channel layers 12 and on the sides of the first metal material formed between the channel layers 12. The first metal material and the second metal material on the sides of the channel layers 12 may form the second gate layers 16, which may thus include each a double metal material. For example, a titanium nitride layer 31 and a tantalum nitride layer 32 may form each second work function metal structure 30.

It may be understood that after the deposition of the first metal material, the work function could be the same all around the channels 12. However, with the further deposition of the second metal material, the work function could change at the sides of the channel layers 12. That is, the second metal material may be deposited in a work function tuning step. The second work function metal structure 30, for example, consisting of the titanium nitride layer 31 and the tantalum nitride layer 32, has in the end the second work function that is different from the first work function of the first work function metal structure 34, which, for example consists of the single titanium nitride layer 31.

Of course, the above example for implementing the method 40 could also produce a different first work function metal structure 34 and a different second work function metal structure 30, respectively. This may depend on which metal material is deposited when and how long, and on how often a change of the deposited metal material is performed. For example, a change between the first metal material and the second metal material could also be made before the gaps between the channel layers 12 are completely filled. In this case, each first work function metal structure 34 would consist of two metal layers, for example, a titanium nitride layer 31 and a tantalum nitride layer 32. Once the gaps are filled completely by these two metal layers, a third metal material could be deposited, for instance, titanium aluminide. In this case, a titanium aluminide layer 33 will form only on the two metal layers 31, 32 that are already formed on the sides of the channel layers 12. Consequently, each second work function metal structure 30 may in the end consist of the titanium nitride layer 31, the tantalum nitride layer 32, and the titanium aluminide layer 33. Many metal material combinations are possible in this way, and the work function tuning can be adapted depending on the type of GAA transistor structure 10 and/or the type of a GAA device made based on the GAA transistor structure.

The present disclosure as described above provides a GAA device with metal gates having a work function mismatch between the side gates (formed by the second metal layers 16) and the inner gates (formed by the first metal layers 13), or generally between the outer gates (formed by the second metal layers 16 and the additional metal layers 21, respectively) and the inner gates. The inner gates may be very thin metal gates (e.g., the first metal layers 13 may be between 1-2 nm; compared to the second metal layers 16, and optionally the additional second metal layers 21, being between 5-7 nm).

Compared with a conventional GAA device, which has no work function mismatch between the inner gates and the outer gates, the GAA device of this disclosure is significantly easier to fabricate at the same channel layer pitch 22. The GAA device of this disclosure also shows a competitive device performance.

The device performance can, for instance, be evaluated by looking at the on-current Iₒₙ and the off-current I_{off} of the GAA device. A drop in the Iₒₙ of the GAA device according to this disclosure is only small with respect to the conventional GAA device, at least for a mismatch between the first work function and the second work function in a range of ±250 meV. It was also found that even when increasing the widths of the channel layers 12 (in the second direction 17), for instance, to channel widths in a range of 10-60 nm, the drop of Iₒₙ is limited to approximately 4%. Thus, a GAA device according to this disclosure, with thin inner metal gates and work function mismatch, is a viable option for a wide range of channel layer 12 widths, and may outperform even a conventional FinFET device.

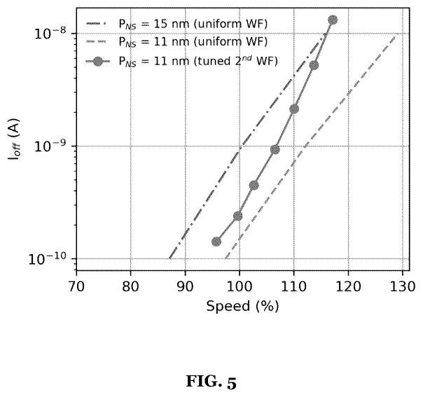

FIG. 5 shows simulated results of a GAA device according to this disclosure (the one with the “tuned 2^{nd} WF”), which includes the GAA transistor structure 10, and two conventional GAA devices (“uniform WF”). The two conventional GAA devices have a channel layer pitch of 11 nm and 15 nm, respectively, while the GAA device according to this disclosure has a channel layer pitch 22 (see FIG. 2) of 11 nm.

The diagram of FIG. 5 analyzes I_{off} (A) vs. speed (%). Here for the same I_{off} the conventional GAA device with 11 nm channel layer pitch is expectedly faster than the conventional GAA device with 15 nm channel layer pitch. The GAA device of this disclosure is in between the two conventional devices. That is, for the same I_{off} than the conventional GAA devices, the GAA device of this disclosure is faster than the conventional GAA device with the 15 nm channel layer pitch. This is despite a loss in Iₒₙ which the GAA device of this disclosure experiences with respect to the conventional GAA devices. Further, the GAA device of this disclosure is only marginally slower than the conventional GAA device with the 11 nm channel layer pitch. Notably, the conventional GAA device with the 11 nm channel layer pitch is only a “hypothetical” device, as it would be nearly impossible to fabricate it in real-life, or only with a technologically very complex process.

In addition, both diagrams of FIG. 5 demonstrate that the GAA device of this disclosure works very well for different values of I_{off}. This means, that the GAA device can be fabricated in different variants with different threshold voltages. Thus, the process to fabricate the GAA transistor structure 10 of this disclosure and the GAA device, respectively, enables multi-Vt-options.

1-20. (canceled)

21. A gate all around, GAA, transistor structure comprising:
a stack of two or more semiconductor channel layers and one or more first gate layers alternatingly arranged along a first direction;
wherein each semiconductor channel layer is encapsulated by a gate dielectric layer, and wherein each first gate layer is arranged between two of the semiconductor channel layers following each other in the first direction; and
two second gate layers sandwiching the stack in a second direction perpendicular to the first direction and connected to the one or more first gate layers;
wherein each first gate layer is made of a first work function metal structure and each second gate layer is made of a second work function metal structure that has a different work function than the first work function metal structure; and
wherein each first gate layer has a first thickness and each second gate layer has a second thickness that is larger than the first thickness.

22. The GAA transistor structure according to claim 21, wherein a ratio of the second thickness to the first thickness is in equal to or larger than 4:1.

23. The GAA transistor structure according to claim 22, wherein the first thickness is in a range of 1-2 nm, and wherein the second thickness is in a range of 5-7 nm.

24. The GAA transistor structure according to claim 21, wherein the first thickness is in a range of 1-2 nm, and wherein the second thickness is in a range of 5-7 nm.

25. The GAA transistor structure according to claim 21, wherein a difference between a first work function of the first work function metal structure and a second work function of the second work function metal structure is in a range of −250 meV to +250 meV.

26. The GAA transistor structure according to claim 25, wherein the GAA transistor structure is an NMOS transistor structure, the first work function is in a range of 4.4-4.6 eV, and the second work function is in a range of the first work function ±250 meV.

27. The GAA transistor structure according to claim 25, wherein the GAA transistor structure is a PMOS transistor structure, the first work function is in a range of 4.6-4.8 eV, and the second work function is in a range of the first work function ±250 meV.

28. The GAA transistor structure according to claim 25, wherein the two or more semiconductor channel layers are arranged with a pitch along the first direction, and wherein the pitch is equal to or below 13 nm.

29. The GAA transistor structure according to claim 21, wherein the two or more semiconductor channel layers are arranged with a pitch along the first direction, and wherein the pitch is equal to or below 13 nm.

30. The GAA transistor structure according to claim 21, wherein the second work function metal structure comprises a set of metal layers, and wherein the first work function metal structure comprises a subset of metal layers included in the set of metal layers.

31. The GAA transistor structure according to claim 21, wherein the second work function metal structure consist of three metal layers respectively made of titanium nitride, tantalum nitride, and titanium aluminide.

32. The GAA transistor structure according to claim 21, wherein the first work function metal structure consist of a single metal layer made of titanium nitride, or consist of two metal layers respectively made of titanium nitride and tantalum nitride.

33. The GAA transistor structure according to claim 21, further comprising two additional second gate layers sandwiching the stack in the first direction and connected to the one or more first gate layers and to the two second gate layers sandwiching the stack in the second direction.

34. The GAA transistor structure according to claim 33, wherein each semiconductor channel layer is formed by a nanosheet; and/or is made of one of silicon, silicon germanium, a III-V semiconductor material, and a 2D material.

35. The GAA transistor structure according to claim 21, wherein each semiconductor channel layer is formed by a nanosheet; and/or is made of one of silicon, silicon germanium, a III-V semiconductor material, and a 2D material.

36. The GAA transistor structure according to claim 21, wherein:
first field effect transistor, FET, structures are formed by the first gate layers, the gate dielectric layers encapsulating the semiconductor channel layers, and the semiconductor channel layers; and
second FET structures are formed by the second gate layers, the gate dielectric layers encapsulating the semiconductor channel layers, and the semiconductor channel layers;
each first FET structure has a first threshold voltage and each second FET structure has a second threshold voltage different than the first threshold voltage.

37. The GAA device comprising the GAA transistor structure according to claims 36, wherein the GAA device is a logic device or an input/output device.

38. The GAA device comprising the GAA transistor structure according to claim 21, wherein the GAA device is a logic device or an input/output device.

39. A method for fabricating a GAA transistor structure, the method comprising:
forming a stack of two or more semiconductor channel layers and one or more first gate layers alternatingly arranged along a first direction;
wherein each semiconductor channel layer is encapsulated by a gate dielectric layer, and wherein each first gate layer is arranged between two of the semiconductor channel layers following each other in the first direction; and
forming two second gate layers sandwiching the stack in a second direction perpendicular to the first direction and connected to the one or more first gate layers;
wherein each first gate layer is made of a first work function metal structure and each second gate layer is made of a second work function metal structure that has a different work function than the first work function metal structure; and
wherein each first gate layer has a first thickness and each second gate layer has a second thickness that is larger than the first thickness.

40. The method according to claim 39, the method further comprising:
forming two additional second gate layers sandwiching the stack in the first direction and connected to the one or more first gate layers and to the two second gate layers sandwiching the stack in the second direction.
